(19) United States
(12) Patent Application Publication
(10) Pub. No.: US 2026/0227442 A1
(43) Pub. Date: Aug. 6, 2026

(54) Circuitry for Staggering Capture Clocks in Testing Electronic Circuits with Multiple Clock Domains

(71) Applicant: Synopsys, Inc., Sunnyvale, CA (US)

(72) Inventors: Bala Tarun Nelapatla, San Jose, CA (US); Likith Kumar Manchukonda, Newark, CA (US); Ke Xue, Shanghai (CN); Mona Marie Marmash, Ashland, MA (US); Peter Wohl, Williston, VT (US)

(21) Appl. No.: 19/146,472

(22) PCT Filed: Jan. 10, 2023
(86) PCT No.: PCT/CN2023/071488

§ 371 Date: Jul. 8, 2025

(51) Int. Cl. G01R 31/3185

(52) U.S. Cl. CPC G01R 31/318552; G01R 31/318536

(57) ABSTRACT

In some aspects, an integrated circuit includes a plurality of clock domains. Each clock domain includes functional circuitry and an on-chip clock controller. The functional circuitry includes scan flip-flops that are connected into one or more scan chains that cross clock domains. The on-chip controllers generate capture pulses that used for scan tests. To run scan tests, test patterns are loaded into the scan chains during scan-in phases clocked by a scan clock, the functional circuitry is operated in response to the test patterns and is clocked by sequences of capture pulses generated by the on-chip clock controllers, and test responses produced by the operation of the functional circuitry are read out from the scan chains during scan-out phases clocked by the scan clock. The on-chip clock controllers generate the capture pulses delayed by stagger periods. The stagger periods are adjustable and are based on the scan clock.

### TECHNICAL FIELD

The present disclosure relates to testing of electronic circuits that have multiple clock domains.

### BACKGROUND

As technology nodes shrink and the complexity and gate count of devices increase, the testing of manufactured integrated circuits becomes increasingly important and increasingly complex. However, testing can be limited if only the logic circuits that are directly connected to the input/output (I/O) pins of the integrated circuit are accessible during testing. With limited access to the interior circuitry of the chip, it can be difficult to set internal signals to test various scenarios and to read internal signals to determine whether circuitry is faulty.

One approach to improve this situation is through the use of scan chains. Scan chains are chains of internal circuits that can be accessed through a chip's I/O pins. In this way, the logic state of internal circuitry can be set to certain values by transmitting those values to the internal circuits through the scan chain. This can be used to set variable states for testing. Once the tests are run, the resulting values at internal circuits may be observed by capturing the values at the internal circuits and then reading out the values through the scan chain. These tests may be referred to as scan tests.

Scan tests are further complicated if the chip under test uses multiple clock domains. Different parts of a chip may be clocked by clocks of different frequencies, which are referred to as clock domains. During scan tests, signals propagating through the circuitry under test may cross between clock domains. Each clock domain crossing may add uncertainty to the timing of the propagating signals and, if not accounted for properly, may result in corrupted or uncertain data which diminishes the value of the scan test.

### SUMMARY

In some aspects, an integrated circuit includes a plurality of clock domains. Each clock domain includes functional circuitry and an on-chip clock controller. The functional circuitry includes scan flip-flops. The scan flip-flops are connected into one or more scan chains that cross clock domains. The on-chip controllers generate capture pulses that are used for scan tests. To run scan tests, test patterns are loaded into the scan chains during scan-in phases clocked by a scan clock. The functional circuitry is operated in response to the test patterns and is clocked by sequences of capture pulses generated by the on-chip clock controllers. Test responses produced by the operation of the functional circuitry are read out from the scan chains during scan-out phases clocked by the scan clock. The on-chip clock controllers are coupled to receive the scan clock and to generate the capture pulses delayed by stagger periods. The stagger periods are adjustable and are based on the scan clock.

Other aspects include components, devices, systems, improvements, methods, processes, applications, computer readable mediums, and other technologies related to any of the above.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 is a block diagram of an integrated circuit with circuitry for implementing stagger periods according to some embodiments of the present disclosure.

FIGS. 1A-1C show operation of the circuitry in FIG. 1 during test mode according to some embodiments of the present disclosure.

FIG. 2 is a block diagram of an on-chip clock controller according to some embodiments of the present disclosure.

FIG. 3 are timing diagrams showing operation of the on-chip clock controller of FIG. 2 according to some embodiments of the present disclosure.

FIG. 4A is a block diagram of a testing system using scan chains in which embodiments of the present disclosure may operate.

FIG. 4B is a flow diagram of operation of the testing system of FIG. 4A.

FIG. 5 depicts a flowchart of various processes used during the design and manufacture of an integrated circuit according to some embodiments of the present disclosure.

FIG. 6 depicts a diagram of an example computer system in which embodiments of the present disclosure may operate.

### DETAILED DESCRIPTION

Aspects of the present disclosure relate to circuitry for staggering capture clocks in testing electronic circuits with multiple clock domains. Scan chains are often used to test the logic functions implemented on integrated circuits. During these tests (referred to as scan tests), some of the functional circuitry that implement the logic functions are interconnected to form a scan chain. The scan chain provides access to sequential circuits, referred to as scan flip-flops or scan flops, in the interior of the device under test (DUT). In this way, interior circuitry can be accessed for testing. Test patterns are loaded into the interior circuitry as needed to run a particular test, and the resulting responses can be captured and compared to the expected outcomes.

In more detail, test patterns are loaded into the scan flip-flops during a scan-in phase, which is clocked by a scan clock. The scan flip-flops are part of the functional circuitry of the integrated circuit. Once the test patterns are loaded, the functional circuitry is operated as stimulated by the test patterns. This operation is clocked by capture pulses, which may be run at the same frequency as the regular clocks used during normal operating mode. These regular clocks will be referred to as functional clocks to distinguish them from the scan clock. The resulting test responses may then be read out from the scan flip-flops during a scan-out phase clocked by the scan clock.

Pulsing many functional clocks for one test pattern can activate more logic per pattern, and therefore reduce the total number of test patterns required and the overall test time. However, the DUT may contain many different clock domains. Unknown timing or otherwise undesirable interactions between asynchronous clock domains can lead to unreliable data at clock domain crossings. For example, some automated testing software cannot easily account for signals crossing clock domains with uncertain or unknown timing, timing uncertainty of propagation of capture pulses generated by on-chip clock controllers, uncertain timing of test control signals such as scan enable signals, or variability resulting from process variations.

As a result, some automated testing software may avoid these situations, for example by not permitting testing across certain combinations of clock domain crossings or by not permitting test patterns that require pulsing of functional clocks in certain orders. Alternatively, test results where there is uncertainty in the result may be marked as unreliable and discarded. In yet another approach, overly conversative timing delays may be introduced to remove all uncertainty for all possible situations. For example, large, fixed timing delays may be introduced into the hardware design of on-chip clock controllers where the delay is designed for the worst-case situation since it is fixed.

In one aspect of the present disclosure, a programmable delay (referred to as the stagger period) between the capture pulses of different clock domains is introduced. This can be used to account for propagation delays and other timing uncertainties at clock domain crossings. In one approach, the stagger period is based on the scan clock. For example, it may be a multiple of the period of the scan clock, where the multiple is adjustable. This approach can be implemented in hardware that does not occupy much area. Some designs described below are based on adding a few registers and counters, with a total gate count of a few dozen gates. Yet, the simple hardware design is robust enough to accommodate different test patterns and different sequences of capture pulses across different clock domain crossings.

Technical advantages of the present disclosure include, but are not limited to, the following. Staggering capture clocks allows more reliable test data to be collected since uncertainties arising from clock domain crossings may be reduced or even eliminated. This in turn reduces the total number of test patterns and total testing time required. An adjustable stagger period provides additional flexibility to tune the amount of stagger so that it is long enough to address uncertainties of clock domain crossings but not longer than may be otherwise necessary. Specific hardware designs, such as those based on counting cycles of a scan clock to determine the stagger period, may be implemented without significantly increasing the area used. In addition, the order of the capture clocks can be changed for different test patterns, providing more freedom for the software generating the test patterns. Staggering capture pulses also generates lower power during capture.

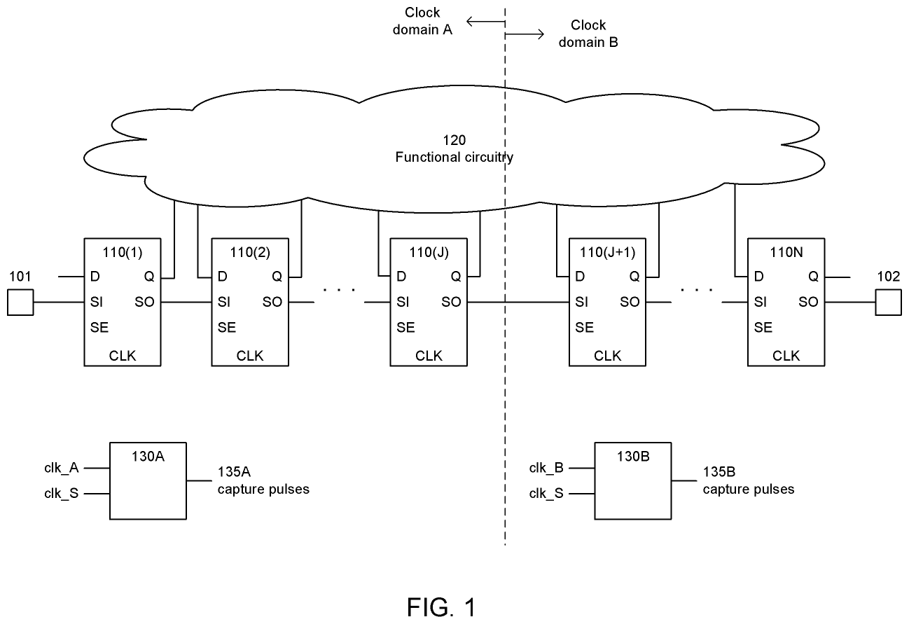

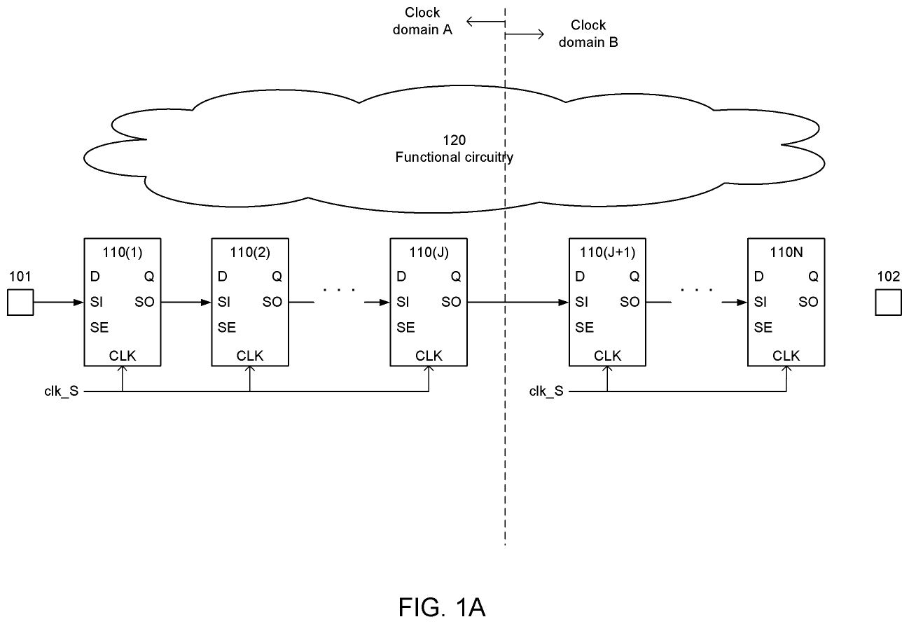

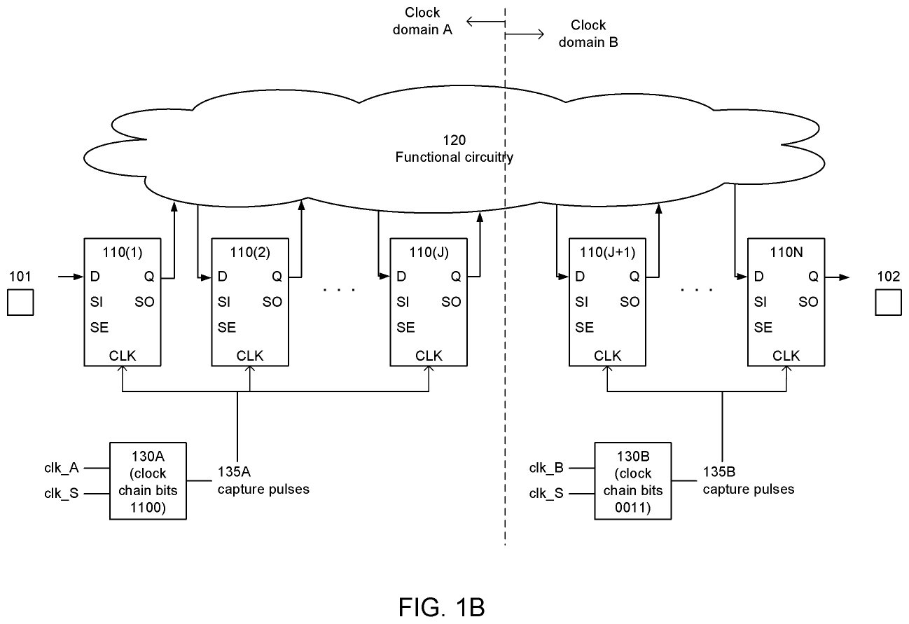

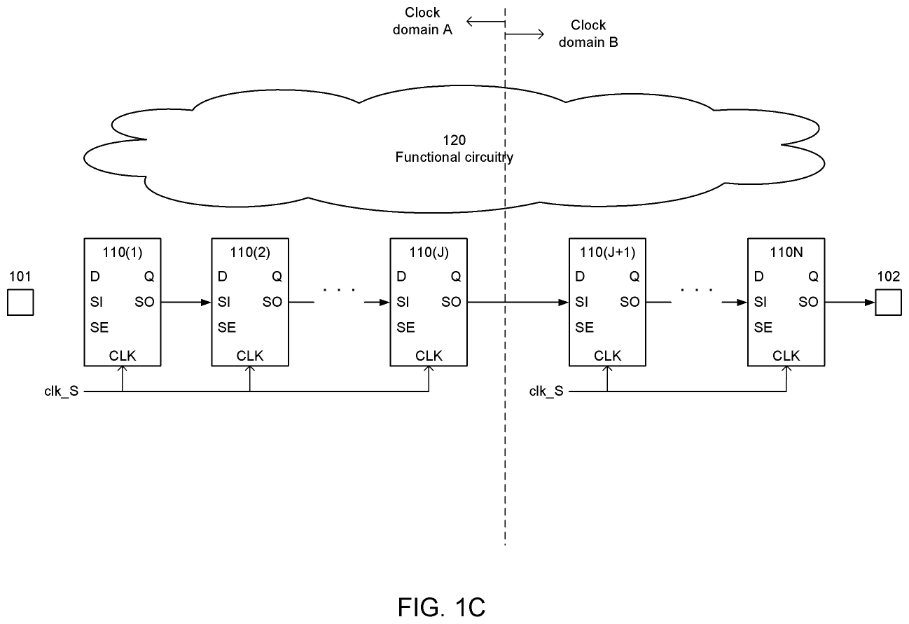

FIG. 1 is a block diagram of an integrated circuit with circuitry for implementing stagger periods according to some embodiments of the present disclosure. The integrated circuit contains functional circuitry, which is the circuitry being tested. In FIG. 1, the functional circuitry is divided into scan flip-flops 110(n) and the rest of the functional circuitry is shown as a cloud 120.

The scan flip-flops 110 in this example are D flip flip-flops, although other sequential circuits may be used. The scan flip-flops 110 have a D input and Q output, which are the normal input and output for a D flip flip-flop. They also have a scan input SI and scan output SO, which are used for scan tests. In many implementations, the Q and SO outputs are the same. A scan enable SE determines whether the scan flip-flop operates in normal operating mode (or functional mode) using D and Q, or in scan shift mode (or test mode) using SI and SO. The scan flip-flops 110 also have a clock input CLK.

In FIG. 1, the integrated circuit includes two clock domains A and B. When the integrated circuit is operating in normal operating mode, the functional circuitry in each clock domain is clocked by a different clock signal, clk_A and clk_B in FIG. 1, which are referred to as the functional clocks. The functional clocks for different clock domains may have different periods and/or other different characteristics, depending on the functional circuitry in that clock domain. A scan clock, clk_S, is used for scan tests. An on-chip clock controller 130A, B for each clock domain produces capture pulses 135A, B used in test mode.

FIGS. 1A-1C show operation of the circuitry in FIG. 1 during test mode, according to some embodiments of the present disclosure. Each figure shows the relevant portion of FIG. 1. FIG. 1A shows a scan-in phase, during which test patterns are read into the scan flip-flops. Scan enable SE is asserted, which selects the ports SI and SO on the scan flip-flops. The scan flip-flops 110 are then connected to form a scan chain: from input pin 101 to scan flip-flop 110(1) . . . to scan flip-flop 110(J), crossing from clock domain A into clock domain B at scan flip-flop 110(J+1) . . . to scan flip-flop 110(N), to output pin 102. The scan flip-flops 110 are clocked by the scan clock clk_S, which may have a different period than the functional clocks since it is used to shift in data to the scan chain (and to shift out data as shown in FIG. 1C).

Once the test patterns are loaded into the scan flip-flops 110, the functional circuitry is run for a controlled number of cycles during a capture phase, as shown in FIG. 1B. The scan enable SE is deasserted. This selects ports D and Q. The scan flip-flops 110 are then connected to the rest of the functional circuitry 120 to form the circuitry that is used in normal operating mode. The on-chip clock controllers 130 generate clock pulses 135 that clock the functional circuitry in a controlled fashion for the loaded test pattern. These are referred to as capture pulses. Because the functional circuitry crosses clock domains, the on-chip clock controllers 130 may delay some of the capture pulses 135 to mitigate uncertainty due to the clock domain crossings. For example, in FIG. 1B, the capture pulses 135B for clock domain B may be delayed relative to the capture pulses 135A for clock domain A to ensure that there is sufficient time for signals to propagate across the clock domain crossing.

FIG. 1C shows a scan-out phase, during which the circuit responses produced by the functional circuitry clocked by the capture pulses are read out from the scan chain. The scan enable SE is asserted, which connects the scan flip-flops 110 into a scan chain. The test responses are then read out through output pin 102, clocked by the scan clock clk_S. The scan-out phase for one test pattern may occur concurrently with the scan-in phase for the next test pattern.

Returning to FIG. 1B, the capture pulses may be “at speed”, meaning that they have the same period as the functional clocks clk_A and clk_B. At speed testing may be used to test for path delay faults or transition faults, for example. Alternatively, the capture pulses may be at different speeds than the functional clocks. Slower capture clocks may be used for some tests, such as testing for stuck-at faults.

As an example for FIG. 1B, on-chip clock controller 130A may generate two capture pulses 135A for clock domain A, followed by on-chip clock controller 130B generating two capture pulses 135B for clock domain B. The sequence of capture pulses may be defined by sequences of bits, referred to as clock chain bits since they define the order in which the clock domains are activated. This example may be represented by a clock chain bit sequence of four bits 1100 for controller 130A and of the four bits 0011 for controller 130B, as shown in FIG. 1B, meaning that controller 130A produces the first two capture pulses #1 and #2, and controller 130B produces the next two capture pulses #3 and #4. The timing of capture pulses within a clock domain is less problematic. For at speed testing, the timing of capture pulses #1 and #2 and the operation of functional circuitry within clock domain A is determined by the functional clock clk_A, and the same situation holds capture pulses #3 and #4 with respect to clock domain B and functional clock clk_B.

However, there is a clock domain crossing between clock domains A and B. There can be uncertainty in the timing of when signals leave scan flip-flop 110(J) in clock domain A and arrive at scan flip-flop 110(J+1) in clock domain B. If capture pulse #3 is generated too early, then the data latched into scan flip-flop 110(J+1) will be unreliable. To mitigate this concern, the on-chip clock controller 130B may delay the generation of capture pulses #3 and #4. That is, the capture clocks for different clock domains may be staggered.

Note that the sequence of capture pulses may be different for different test patterns. The next test pattern may have a sequence of one capture pulse for clock domain A, followed by one capture pulse for clock domain B. The order of the clock domains may also be changed, for example a sequence with capture pulses for clock domain B followed by capture pulses for clock domain A. In addition, FIG. 1 shows only a single scan chain with one clock domain crossing. The integrated circuit typically will contain many scan chains, and each scan chain may have multiple clock domain crossings between different clock domains in different orders, and many different test patterns and sequences of capture pulses will be applied to each scan chain.

It is advantageous if the on-chip clock controllers for the different clock domains all have the same logical design and if the design does not require much area, but while still being able to accommodate the different variations in scan chains, sequences of capture pulses, and clock domain crossings. In some designs, the delay or stagger period introduced by the on-chip clock controllers is adjustable. It may be increased or decreased to accommodate different situations. In addition, the stagger period may be based on the scan clock. This is advantageous because the scan clock is already available in test mode, since it is used for the scan-in and scan-out phases.

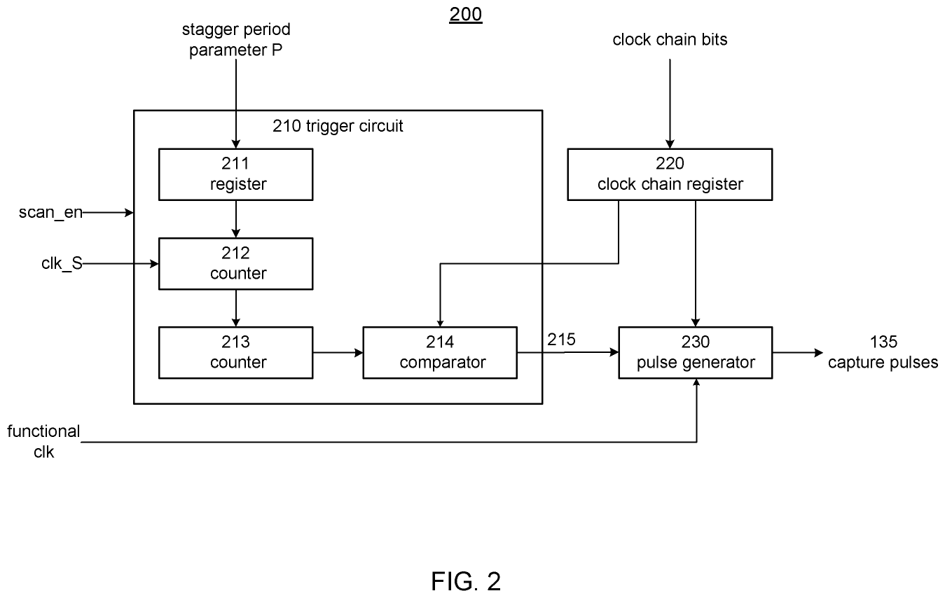

FIG. 2 is a block diagram of an on-chip clock controller 200 according to some embodiments of the present disclosure. The controller 200 includes a trigger circuit 210, a clock chain register 220 and a pulse generator 230. The clock chain register 220 stores the sequence of clock chain bits that defines the capture pulses for the controller. In the above example, the register 220 for clock domain B stores the clock chain bit sequence 0011 to indicate that controller 200 for clock domain B generates pulses #3 and #4. The trigger circuit 210 produces a pulse trigger 215, which signals to the pulse generator 230 that it should produce the sequence of pulses defined by the clock chain bit sequence stored in register 220.

The trigger circuit 210 produces a pulse trigger 215 that is delayed by an adjustable amount. In this example, the adjustable delay is based on a stagger period, which is defined by a parameter P. The trigger circuit 210 also receives the scan clock clk_S, and the scan enable signal scan_en. A transition in scan_en signals when the capture phase begins. The trigger circuit 210 then produces the pulse trigger 215, delayed by a stagger period that is based on the scan clock clk_S and the stagger period parameter P.

The pulse generator 230 then produces the sequence of capture pulses: pulses #3 and #4 in this example. If the testing is at speed, pulses #3 and #4 will have the same period as the functional clock for the clock domain, which is clk_B in this example.

FIG. 2 also shows an example design for the trigger circuit 210. In this design, the stagger period parameter P is an integer, and the design functions to delay the capture pulses by a delay that is based on the parameter P. This design includes a register 211, two counters 212, 213, and a comparator 214. The register 211 stores the parameter P. Let P=4 for purposes of illustration. The first counter 212 counts cycles of the scan clock clk_S up to P. The second counter 213 then counts cycles from the first counter. The comparator 214 determines when the count of the second counter 213 reaches the first clock chain bit that equals 1 (for pulse #3 in this example). When that happens, the trigger circuit 210 generates the pulse trigger 215.

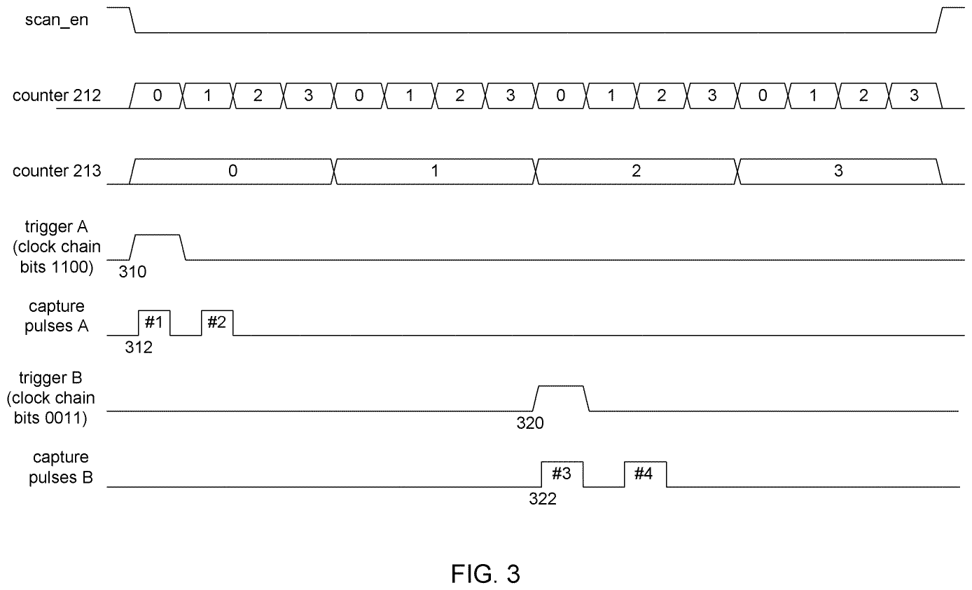

FIG. 3 are timing diagrams showing operation of the on-chip clock controller of FIG. 2. Signals are shown for both clock domain A and clock domain B. When the scan enable scan_en is deasserted, this signals that the scan-in phase is done and the capture phase starts. The counter 212 counts up to P=4, timed by cycles of the scan clock. In FIG. 3, the count is shown as 0, 1, 2, 3, and then repeating. Counter 213 counts cycles of the first counter 212, also counting 0, 1, 2, 3, because in this example there are 4 clock chain bits.

The next two timing signals show the generation of capture pulses #1 and #2 for clock domain A. For clock domain A, the clock chain bit sequence is 1100, as listed in FIG. 3.

The first clock chain bit is a 1, so comparator A signals a match when counter 213 is at 0. This produces pulse trigger A at 310, and then the two captures pulses #1 and #2 starting at 312 after some propagation delay. These capture pulses are in clock domain A and, for stuck-at testing and at speed testing, the spacing of these pulses is determined by the functional clock clk_A. The pulse trigger is delayed but, once triggered, the capture pulses themselves are timing-accurate.

The last two timing signals show the generation of capture pulses #3 and #4 for clock domain B. The clock chain bit sequence for clock domain B is 0011, as listed in FIG. 3. Comparator B signals a match when counter 213 is at 2. This produces pulse trigger B at 320, and then the two captures pulses #3 and #4 starting at 322. For at speed testing, the spacing of these pulses is determined by the functional clock clk_B. In FIG. 3, pulses #3 and #4 in clock domain B have a different frequency than pulses #1 and #2 in clock domain A. The timing of counter 212 is determined by clk_S, the period of capture pulses #1 and #2 are determined by clk_A, and the period of capture pulses #3 and #4 are determined by clk_B, as can be seen from the different widths of these pulses in FIG. 3.

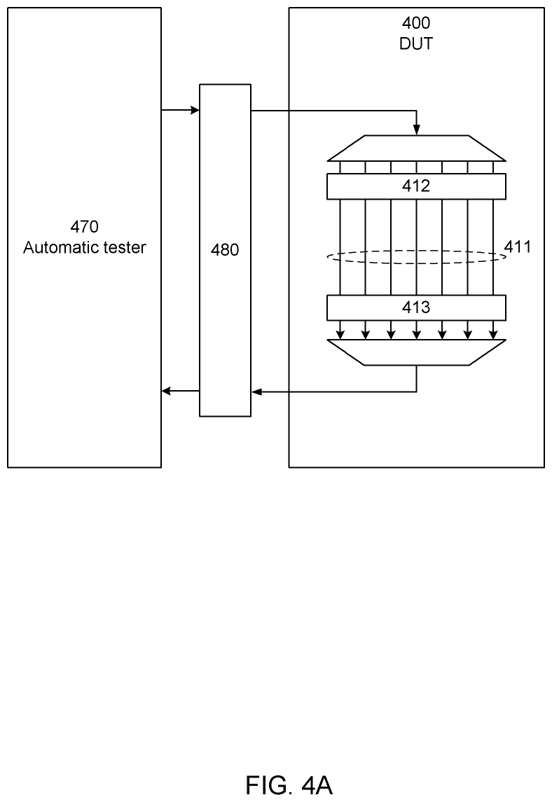

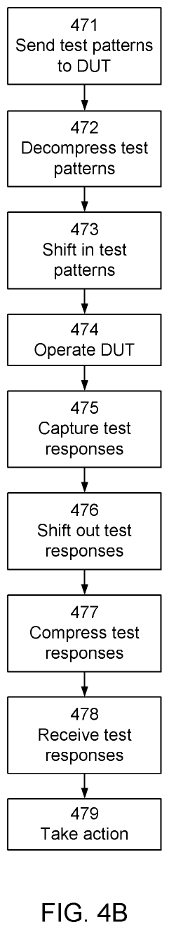

FIG. 4A is a block diagram of a testing system using scan chains in accordance with some embodiments of the present disclosure. FIG. 4B is a flow diagram of operation of the testing system of FIG. 4A. The testing system includes a device under test (DUT) 400, an automatic tester 470, and a test interface 480 between the two. The automatic tester 470 runs scan tests on the DUT 400. These scan tests make use of scan chains 411 that may cross multiple clock domains, as described herein. Data transmitted between the tester 470 and the DUT 400 may be compressed, so the DUT may include a data decompressor 412 and a data compressor 413.

Referring to FIG. 4B, the tester 470 runs scan tests as follows. At 471, the tester 470 sends test patterns to the DUT. This data is used to set internal circuitry to the initial states for the desired test. The test setup data is sent in compressed form to the DUT. This test setup data may include parameters for determining the stagger periods for the tests. At 472, the data decompressor 412 within the DUT decompresses the setup data and, at 473, it shifts the data into scan flip-flops via the logic scan chains 411.

At 474, the DUT then operates, moving forward from the initial state set by the tester 470. Capture pulses with adjustable stagger periods are generated as described herein. At 475, the corresponding scan test responses are captured into the corresponding scan flip-flops. At 476, the respective scan test responses are shifted out. The scan test responses are shifted out via the scan chains 411. At 477, the data compressor 413 within the DUT may compress the data, so that less bandwidth is required to transmit this data from the DUT off-chip and back to the tester.

At 478, the tester 470 receives the scan test responses. The data from different scan chains may be multiplexed in order to reduce the number of pins on the DUT 400. At 479, the tester 470 or other components may then take appropriate actions based on the sensor data. Many different actions are possible.

Referring to FIG. 4A, different granularities for the on-chip clock controllers and stagger periods are possible. The DUT 400 contains many scan chains 411, each of which may cross multiple clock domains. The on-chip controllers are hardware circuits fabricated on the DUT. In one approach, the same circuit design is used for all of the on-chip clock controllers on the DUT. The same parameterization of the stagger period may be used for all clock domains. The value for the stagger period parameter(s) may be the same for all clock domains. The value may be selected to provide the shortest stagger period that avoids timing uncertainty at the clock domain crossings.

In approaches that provide more adjustability, different designs may be used for different scan chains, for different clock domains, or for different clock domains within each scan chain. For example, the useful range of stagger periods for a clock domain may depend on which other clock domains appear before or after it. The design of the on-chip clock controller may change to implement different parameterizations of the stagger period, in order to be better matched to the useful range of stagger periods for each situation.

As another example, depending on the implementation of on-chip clock controllers, the stagger periods may be set independently for different clock domains, for different scan chains, and/or for different test patterns. For example, the stagger period may be determined based on the order of clock domains in the scan tests. As another example, the stagger period may be the same for a set of test patterns that are run concurrently, but may be changed for a different set of test patterns run at a different time. Other variations will be apparent.

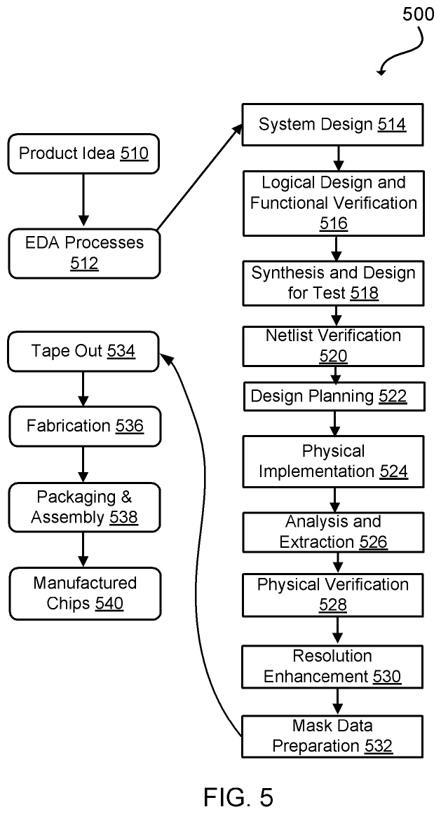

FIG. 5 illustrates an example set of processes 500 used during the design, verification, and fabrication of an article of manufacture such as an integrated circuit to transform and verify design data and instructions that represent the integrated circuit. Each of these processes can be structured and enabled as multiple modules or operations. The term ‘EDA’ signifies the term ‘Electronic Design Automation.’ These processes start with the creation of a product idea 510 with information supplied by a designer, information which is transformed to create an article of manufacture that uses a set of EDA processes 512. When the design is finalized, the design is taped-out 534, which is when artwork (e.g., geometric patterns) for the integrated circuit is sent to a fabrication facility to manufacture the mask set, which is then used to manufacture the integrated circuit. After tape-out, a semiconductor die is fabricated 536 and packaging and assembly processes 538 are performed to produce the finished integrated circuit 540.

Specifications for a circuit or electronic structure may range from low-level transistor material layouts to high-level description languages. A high-level of representation may be used to design circuits and systems, using a hardware description language (‘HDL’) such as VHDL, Verilog, System Verilog, SystemC, MyHDL or Open Vera. The HDL description can be transformed to a logic-level register transfer level (‘RTL’) description, a gate-level description, a layout-level description, or a mask-level description. Each lower representation level that is a more detailed description adds more useful detail into the design description, for example, more details for the modules that include the description. The lower levels of representation that are more detailed descriptions can be generated by a computer, derived from a design library, or created by another design automation process. An example of a specification language at a lower level of representation language for specifying more detailed descriptions is SPICE, which is used for detailed descriptions of circuits with many analog components. Descriptions at each level of representation are enabled for use by the corresponding systems of that layer (e.g., a formal verification system). A design process may use a sequence depicted in FIG. 5. The processes described by be enabled by EDA products (or EDA systems).

During system design 514, functionality of an integrated circuit to be manufactured is specified. The design may be optimized for desired characteristics such as power consumption, performance, area (physical and/or lines of code), and reduction of costs, etc. Partitioning of the design into different types of modules or components can occur at this stage.

During logic design and functional verification 516, modules or components in the circuit are specified in one or more description languages and the specification is checked for functional accuracy. For example, the components of the circuit may be verified to generate outputs that match the requirements of the specification of the circuit or system being designed. Functional verification may use simulators and other programs such as testbench generators, static HDL checkers, and formal verifiers. In some embodiments, special systems of components referred to as ‘emulators’ or ‘prototyping systems’ are used to speed up the functional verification.

During synthesis and design for test 518, HDL code is transformed to a netlist. In some embodiments, a netlist may be a graph structure where edges of the graph structure represent components of a circuit and where the nodes of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 520, the netlist is checked for compliance with timing constraints and for correspondence with the HDL code. During design planning 522, an overall floor plan for the integrated circuit is constructed and analyzed for timing and top-level routing.

During layout or physical implementation 524, physical placement (positioning of circuit components such as transistors or capacitors) and routing (connection of the circuit components by multiple conductors) occurs, and the selection of cells from a library to enable specific logic functions can be performed. As used herein, the term ‘cell’ may specify a set of transistors, other components, and interconnections that provides a Boolean logic function (e.g., AND, OR, NOT, XOR) or a storage function (such as a flipflop or latch). As used herein, a circuit ‘block’ may refer to two or more cells. Both a cell and a circuit block can be referred to as a module or component and are enabled as both physical structures and in simulations. Parameters are specified for selected cells (based on ‘standard cells’) such as size and made accessible in a database for use by EDA products.

During analysis and extraction 526, the circuit function is verified at the layout level, which permits refinement of the layout design. During physical verification 528, the layout design is checked to ensure that manufacturing constraints are correct, such as DRC constraints, electrical constraints, lithographic constraints, and that circuitry function matches the HDL design specification. During resolution enhancement 530, the geometry of the layout is transformed to improve how the circuit design is manufactured.

During tape-out, data is created to be used (after lithographic enhancements are applied if appropriate) for production of lithography masks. During mask data preparation 532, the ‘tape-out’ data is used to produce lithography masks that are used to produce finished integrated circuits.

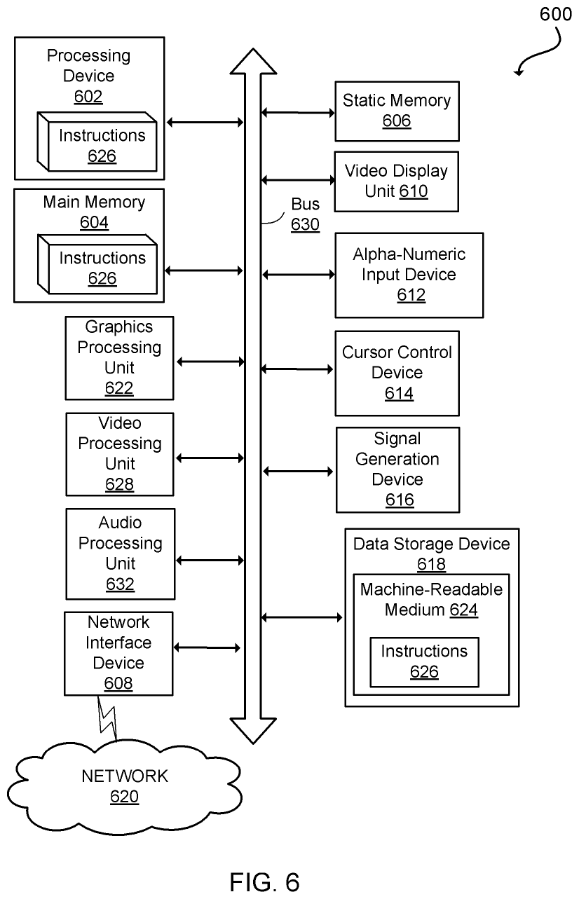

A storage subsystem of a computer system (such as computer system 600 of FIG. 6) may be used to store the programs and data structures that are used by some or all of the EDA products described herein, and products used for development of cells for the library and for physical and logical design that use the library.

FIG. 6 illustrates an example machine of a computer system 600 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM), a static memory 606 (e.g., flash memory, static random access memory (SRAM), etc.), and a data storage device 618, which communicate with each other via a bus 630.

Processing device 602 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 may also be one or more special-purpose processing devices such as an application specific integrated circuit (ASIC), a field programmable gate array (FPGA), a digital signal processor (DSP), network processor, or the like. The processing device 602 may be configured to execute instructions 626 for performing the operations and steps described herein.

The computer system 600 may further include a network interface device 608 to communicate over the network 620. The computer system 600 also may include a video display unit 610 (e.g., a liquid crystal display (LCD) or a cathode ray tube (CRT)), an alphanumeric input device 612 (e.g., a keyboard), a cursor control device 614 (e.g., a mouse), a graphics processing unit 622, a signal generation device 616 (e.g., a speaker), graphics processing unit 622, video processing unit 628, and audio processing unit 632.

The data storage device 618 may include a machine-readable storage medium 624 (also known as a non-transitory computer-readable medium) on which is stored one or more sets of instructions 626 or software embodying any one or more of the methodologies or functions described herein. The instructions 626 may also reside, completely or at least partially, within the main memory 604 and/or within the processing device 602 during execution thereof by the computer system 600, the main memory 604 and the processing device 602 also constituting machine-readable storage media.

In some implementations, the instructions 626 include instructions to implement functionality corresponding to the present disclosure. While the machine-readable storage medium 624 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 602 to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. An integrated circuit comprising:
a plurality of clock domains, each clock domain comprising:
functional circuitry that include scan flip-flops; and
an on-chip clock controller that generates capture pulses;
wherein:
the scan flip-flops are connected into one or more scan chains that cross clock domains;
test patterns are loaded into the scan chains during scan-in phases clocked by a scan clock; the functional circuitry is operated in response to the test patterns and is clocked by sequences of capture pulses generated by the on-chip clock controllers; and test responses produced by the operation of the functional circuitry are read out from the scan chains during scan-out phases clocked by the scan clock; and
the on-chip clock controllers are coupled to receive the scan clock and to generate the capture pulses delayed by adjustable stagger periods that are based on the scan clock.

2. The integrated circuit of claim 1 wherein the on-chip clock controllers for different clock domains all have a same logical design.

3. The integrated circuit of claim 1 wherein the sequence of capture pulses for each test pattern is defined by a corresponding sequences of clock chain bits, and the on-chip clock controllers are further coupled to receive the clock chain bit sequences and to generate the sequences of capture pulses based on the clock chain bit sequences.

4. The integrated circuit of claim 1 wherein the stagger periods are defined by a stagger period parameter, and the on-chip clock controllers for different clock domains are further coupled to receive the same stagger period parameter.

5. The integrated circuit of claim 4 wherein the sequence of capture pulses is different for different test patterns, but the stagger period parameter is the same for the different sequences of capture pulses.

6. The integrated circuit of claim 1 wherein, for at least some of the test patterns, the capture pulses for the clock domains have a same period as functional clocks for those clock domains.

7. The integrated circuit of claim 6 wherein at least some of the test patterns test for path delay faults or transition faults.

8. An on-chip clock controller comprising a trigger circuit coupled to receive a scan clock and an adjustable stagger period parameter and further coupled to output a pulse trigger; wherein the pulse trigger is delayed by a stagger period that is based on the scan clock and the stagger period parameter, the on-chip clock controller produces a sequence of one or more capture pulses in response to the pulse trigger, the scan clock is used to clock scan-in and scan-out phases of a scan chain, and the capture pulses are used to clock operation of functional circuitry that includes the scan chain in response to test patterns loaded into the scan chain.

9. The on-chip clock controller of claim 8 wherein the stagger period is the stagger period parameter times a period of the scan clock.

10. The on-chip clock controller of claim 8 wherein the stagger period parameter is an integer, and the on-chip clock controller further comprises:
a register that stores the received stagger period parameter.

11. The on-chip clock controller of claim 8 further comprising:
a first counter that counts cycles of the scan clock in a quantity equal to the stagger period parameter.

12. The on-chip clock controller of claim 11 further comprising:
a second counter coupled to an output of the first counter, wherein the second counter counts cycles of the first counter.

13. The on-chip clock controller of claim 8 further comprising:
a register that stores a sequence of clock chain bits that defines the sequence of capture pulses for the on-chip clock controller; and
a pulse generator coupled to receive the clock chain bit sequence from the register and to receive the pulse trigger from the trigger circuit, and to produce the sequence of capture pulses in response to the pulse trigger and in accordance with the clock chain bit sequence.

14. A method comprising:
receiving a scan clock, wherein a scan-in phase and a scan-out phase of a scan chain are clocked by the scan clock;
determining an adjustable stagger period based on the scan clock; and
producing a sequence of one or more capture pulses that is delayed by the stagger period, wherein the sequence of capture pulses are used to clock operation of functional circuitry that includes the scan chain in response to test patterns loaded into the scan chain.

15. The method of claim 14 wherein the stagger period is an integer multiple of a period of the scan clock.

16. The method of claim 15 wherein the scan chain crosses into an adjacent clock domain, and the stagger period is a lowest integer multiple of the period of the scan clock that avoids timing ambiguity at the clock domain crossing during operation of the functional circuitry.

17. The method of claim 14 wherein the stagger period varies based on the test patterns.

18. The method of claim 14 wherein the scan chain crosses into different clock domains for different test patterns, and the stagger period varies based on an order of the clock domain crossings.

19. The method of claim 14 wherein the stagger period is the same across the different test patterns.

20. The method of claim 14 wherein the stagger period determines a timing of a first in the sequence of capture pulses.
